(19) United States
(12) Patent Application Publication
(10) Pub. No.: US 2025/0062732 A1
(43) Pub. Date: Feb. 20, 2025

(54) Rail-to-rail nMOS Amplifier

(71) Applicant: Renesas Design (UK) Limited, Bourne End (GB)

(72) Inventors: Hiroki ASANO, Ichikawa-shi (JP); Tetsuro OKURA, Yokohama-shi (JP)

(73) Assignee: Renesas Design (UK) Limited, Bourne End (GB)

(21) Appl. No.: 18/452,265

(22) Filed: Aug. 18, 2023

(51) Int. Cl. H03F 3/45; H03F 1/02; H03F 1/32

(52) U.S. Cl. CPC H03F 3/45183; H03F 1/0288; H03F 1/3211; H03F 3/45273

(57) ABSTRACT

An amplifier assembly suitable for use as a rail-to-rail amplifier is provided. The amplifier assembly includes: a first input circuit connected to a first signal input node for a first input level range; a second input circuit connected to a second signal input node for a second input level range; a load circuit coupled to the first input circuit, the second input circuit and an output node of the amplifier assembly, wherein the first input circuit includes a first auxiliary control transistor element, and a first control transistor element. The first signal input node is coupled to a control terminal of the first control transistor element and a control terminal of the first auxiliary control transistor element. A path connected in parallel to the first control transistor element includes the first auxiliary control transistor element.

### TECHNICAL BACKGROUND

The present disclosure is related to a signal buffer. Signal buffers are widely employed in analog front ends, where an input signal is provided to the analog front end via the signal buffer. In order to handle a wide range of input signal voltages, the signal buffer is typically required to operate rail-to-rail.

In Phillip E. Allen, Douglas R. Holberg, CMOS Analog Circuit Design, Oxford University Press, 2011 examples of signal buffers are shown, where single p-MOS, single n-MOS and a combination of n-MOS and p-MOS transistors as input stages are used. However, p-MOS or n-MOS transistors as the input stage have limited voltage range and therefore do not necessarily satisfy system requirements. On the other hand, the combination of p-MOS and n-MOS is well known as suitable for a rail-to-rail input stage topology. However, because this setup requires constant transconductance gm circuit and folded cascade as load stage, using both of constant transconductance gm and folded cascade stage increase signal quiescent current Iq and implementation area. Moreover, they increase complexity of the overall circuit structure.

### Problem to be Solved

To address the above issues, an amplifier assembly is required that provides rail to rail operation, low power operation, and a minimum die area.

### SUMMARY

To overcome the above stated problem the present disclosure provides an amplifier assembly that suitable for use as a rail-to-rail amplifier.

The amplifier assembly includes a first input circuit connected to a first signal input node; a second input circuit connected to a second signal input node; a load circuit coupled to the first input circuit, the second input circuit and an output node of the amplifier assembly. The first input circuit includes a first auxiliary control transistor element, and a first control transistor element, wherein the first signal input node is coupled to a control terminal of the first control transistor element and a control terminal of the first auxiliary control transistor element; and a path connected in parallel to the first control transistor element includes the first auxiliary control transistor element. By the first signal input node a first input signal may be provided to the amplifier assembly. By the second signal input node a second input signal may be provided. At the first signal input node a signal having a first input level range may be provided. At the second signal input node a signal having a second input level range may be provided. In some embodiments, the first input level range and the second input level range may be identical, may overlap, may be in parts different, or may be completely different.

The term “connected in parallel” may specify the kind of circuit connections. In some embodiments, the term “connected in parallel” may not specify a layout order.

The configuration of the amplifier assembly leads to a higher linearity of the amplifier assembly, in particular for low input voltages at the first input node, by means of the first auxiliary control transistor element. As a consequence, an amplifier assembly having a small die area and low power operation is provided. Further, an input voltage offset may be reduced due to the linearity compensation by the first auxiliary control transistor element. Thus, good accuracy is achieved with a small implementation area even for small input voltages. A small input offset voltage with small area also helps to reduce costs for an increased rail-to-rail input voltage range without complicated circuit.

In some embodiments, the first input circuit may include a first clamping circuit, wherein the path connected in parallel to the first control transistor element may include, connected in series, the first clamping circuit. By means of the first clamping circuit a working point of the first auxiliary control transistor element may be defined. Thus, negative affects of the first auxiliary control transistor elements on the behaviour of the first control transistor at high input voltages at the first signal input node are avoided. Summarizing, a rail-to-rail amplifier assembly may be provided having a high linearity within the complete/a large rail-to-rail range.

In some embodiments, the first clamping circuit may include a first clamping transistor element, wherein a control terminal of the first clamping transistor element is controlled by an electrical quantity at a biasing input node. Thus, biasing of the first auxiliary control transistor element may be adapted very flexible and precise and, therefore, accuracy of the transfer function may be improved. Further, discrepancies of the first auxiliary control transistor element and the first control transistor element as well as other discrepancies may be adjusted efficiently with low effort.

In some embodiments, the second input circuit may include a second auxiliary control transistor element, and a second control transistor element, wherein the second signal input node may be coupled to a control terminal of the second control transistor element and a control terminal of the second auxiliary control transistor element; and a path connected in parallel to the second control transistor element may include the second auxiliary control transistor element.

Thus, an amplifier assembly may be provided wherein a higher linearity of the amplifier assembly, in particular for low input voltages, is provided for both, the first and the second signal input node, by means of the first and second auxiliary control transistor elements. As a consequence, an amplifier assembly having a small die area and low power operation is provided. Further, an input voltage offset may be reduced due to the linearity compensation by the second auxiliary control transistor element. Thus, good accuracy is achieved with a small implementation area even for small input voltages. A small input offset voltage with small area also helps to reduce costs for an increased rail-to-rail input voltage range without complicated circuit.

In some embodiments, the second input circuit may include a second clamping circuit, wherein the path connected in parallel to the second control transistor element may include, connected in series, the second clamping circuit. Thus, negative effects of the second auxiliary control transistor elements on the behaviour of the first control transistor at high input voltages at the second signal input node are avoided. Summarizing, a rail-to-rail amplifier assembly may be provided having a high linearity within the complete/a large rail-to-rail range when operating the second signal input circuit.

In some embodiments, the second clamping circuit may include a second clamping transistor element, wherein a control terminal of the second clamping transistor element may be controlled by an electrical quantity at a biasing input node. Thus, biasing of the second auxiliary control transistor element may be adapted very flexible and precise and, therefore, accuracy of the transfer function may be improved. Further, discrepancies of the second auxiliary control transistor element and the second control transistor element as well as other discrepancies may be compensated efficiently with low effort.

In some embodiments, the biasing input node coupled to the first clamping transistor element may be coupled to the biasing input node coupled to the second clamping transistor element. Therefore, biasing may be simplified and executed very fast.

In some embodiments, the biasing input node coupled to the first clamping transistor element may be in parts or completely decoupled from the biasing input node coupled to the second clamping transistor element. Therefore, biasing may be provided more accurate and, therefore, overall linearity of the amplifier assembly may be improved, in particular in case of discrepancies between the first input circuit and the second input circuit.

In some embodiments, the first clamping transistor element, the first auxiliary control transistor element, the first control transistor element, the second clamping transistor element, the second auxiliary control transistor element, and/or the second control transistor element may be n-MOS transistor elements. In some embodiments, all transistor elements of the first input circuit and/or of the second input circuit may be n-MOS transistor elements. Using n-MOS transistor elements for the first and second input circuit may improve handling of high input voltages applied to the first and/or second signal input node.

In some embodiments, the first clamping transistor element, the first auxiliary control transistor element, the second clamping transistor element, and/or the second auxiliary control transistor element may be native MOS transistor elements. A reduced threshold voltage of the first and/or second auxiliary control transistor element may improve sensitivity with regard to low voltages at the first and/or second signal input nodes. This leads to an improved compensation of offset voltages at the first and/or second control transistor elements and, therefore, to an increased linearity of the amplifier assembly at low input voltages. Further, a native input stage, including one or more of the following group: the first auxiliary control transistor element, the second auxiliary control transistor element, the first clamping transistor element, the second clamping transistor element, may help to extend the input voltage range of the amplifier and may reduce an input offset voltage at low-input voltage. In addition, using a native transistor element as a clamping transistor element may help to change over from a native MOS first/second auxiliary control transistor element to a standard MOS first/second control transistor element as analog operation. Therefore, transition from native to standard MOS may be executed smoothly.

In some embodiments, the first control transistor element and/or the second control transistor element may be standard MOS transistor elements. This may lead to a linear transfer function of the amplifier assembly for medium and high input voltages.

In some embodiments, the load circuit may include an output transistor element for controlling an output of the amplifier assembly based on an output electrical quantity of the first input circuit and based on an output electrical quantity of the second input circuit. This may have the advantage that a high output voltage close to a supply voltage of the amplifier assembly may be possible (rail-to-rail out).

In some embodiments, the load circuit may include an output transistor element, wherein the first input circuit and the second input circuit may affect an electrical quantity at a control terminal of the output transistor element. This may have the advantage that a high output voltage close to a supply voltage of the amplifier assembly may be possible (rail-to-rail out).

In some embodiments, the load circuit may include a current mirror circuit and an output transistor element, wherein the current mirror circuit may be coupled to the first input circuit, the second input circuit and the output transistor element, and the output transistor element may control an output of the amplifier assembly. This allows a simple and efficient coupling between the first input circuit and the second input circuit to control an output of the amplifier assembly.

In some embodiments, the load circuit may include an output transistor element, a first load transistor element and a second load transistor element, wherein the first input circuit may be coupled to the control terminal of the first load transistor element, to the control terminal of the second load transistor element, and to the channel of the first load transistor element. The second input circuit may be coupled to the channel of the second load transistor element and to the control terminal of the output transistor element, and the channel of the output transistor element may be coupled to the output of the amplifier assembly. This allows a simple and efficient coupling between the first input circuit and the second input circuit to control an output of the amplifier assembly.

In some embodiments, the output transistor element, the first load transistor element and/or the second load transistor element may be p-MOS transistor elements. In some embodiments all transistor elements of the load circuit may be p-MOS transistor elements. This may have the advantage that a higher output voltage range, in particular closer to the supply voltage, may be output. Further, an overall leakage current may be reduced.

In some embodiments, the output transistor element, the first load transistor element and/or the second load transistor element may be standard MOS transistor elements. In some embodiments all transistor elements of the load circuit may be standard MOS transistor elements. Thus, overall size of the amplifier assembly may be reduced and transconductance may be improved. Therefore, efficiency of the amplifier assembly is increased.

In some embodiments, the output of the amplifier assembly may be coupled to the first signal input node or to the second signal input node. Thus, a simple and efficient voltage follower with a large voltage range and low losses can be provided.

Summarizing, an amplifier assembly may be provided, wherein a rail-to-rail range is improved and a circuit is simplified in that an auxiliary control transistor element is connected in parallel to a control transistor element of an input circuit, which is connected to an input node. The drain-source voltage of the auxiliary control transistor element may be dominant compared to the drain-source voltage of the control transistor element regarding the output of the respective input circuit at low input voltages, whereas the auxiliary control transistor element may be decoupled at higher input voltages by a clamping circuit, in particular by a clamping transistor. Thus, the drain-source voltage of the control transistor element may be dominant compared to the drain-source voltage of the auxiliary control transistor element regarding the output of the respective input circuit at high input voltages.

Therefore, an amplifier assembly having a very linear transfer function, a small input offset voltage, a small die area and a large rail-to-rail range is provided. In detail, a small input offset voltage with small area brings to achieve good accuracy. A small input offset voltage with small area also helps to reduce trimming cost. Further, a rail-to-rail input voltage range is increased without a complicated circuit which leads to energy savings and, therefore less heat dissipation. In addition, a small implementation area is only needed, since the circuit for a large rail-to-rail amplifier assembly is simplified. Using native n-MOS as clamping transistor elements may help to do transition smoothly from native n-MOS input stage (from a native n-MOS auxiliary control transistor element) to standard n-MOS input stage (to a standard n-MOS control transistor element). Finally, a rail-to-rail operation without a constant transconductance gm circuit enables to achieve a low signal quiescent current operation (Iq current operation).

### BRIEF DESCRIPTION OF THE DRAWINGS

FIG. 1 shows schematically an example of an amplifier assembly according to an embodiment.

FIG. 2 shows schematically an example of an amplifier assembly according to another embodiment.

FIG. 3 shows schematically an example of an amplifier assembly according to an embodiment.

FIG. 4 shows schematically an example of an amplifier assembly according to an embodiment being used as a voltage follower.

FIG. 5 shows schematically example of transfer functions of an amplifier assembly according to embodiments being connected as shown in FIG. 4.

FIG. 6a shows schematically an example of a dependency of the transfer functions on temperature of an amplifier assembly according to an embodiment, wherein the first auxiliary control transistor element, the second auxiliary control transistor element, the first clamping transistor element and the second transistor clamping element are standard transistor elements.

FIG. 6b shows schematically an example of a dependency of the transfer functions on temperature of an amplifier assembly according to an embodiment, wherein the first auxiliary control transistor element, the second auxiliary control transistor element, the first clamping transistor element and the second clamping transistor element are native transistor elements.

FIG. 7a and FIG. 7b show schematically an example of an error between the transfer functions shown in FIGS. 6a and 6b and an ideal, linear rail-to-rail transfer function, respectively.

FIG. 8a shows an example of the result of a Monte Carlo simulation across temperature of an amplifier assembly according to an embodiment wherein the auxiliary control transistor elements are standard MOS transistor elements.

FIG. 8b shows an example of the result of a Monte Carlo simulation across temperature of an amplifier assembly according to an embodiment wherein the auxiliary control transistor elements are native MOS transistor elements.

FIG. 9 shows schematically an example of a measurement results of a PWM converter across supply voltage and temperature, wherein an amplifier assembly as shown by one of FIG. 1 to FIG. 3 is used.

### DESCRIPTION OF EXAMPLE EMBODIMENTS

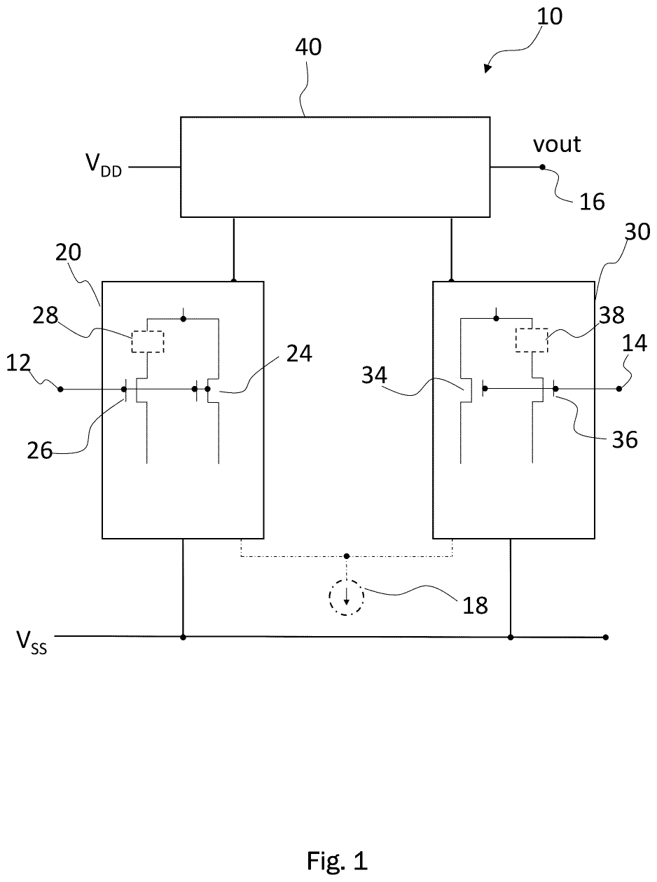

FIG. 1 schematically shows an example of an amplifier assembly 10 according to an embodiment of the disclosure. The amplifier assembly 10 is suitable for use as a rail-to-rail amplifier and includes a first input circuit 20 connected to a first signal input node 12 for a first input level range; a second input circuit 30 connected to a second signal input node 14 for a second input level range; a load circuit 40 coupled to the first input circuit 20, the second input circuit 30 and an output node 16 of the amplifier assembly 10. The first input circuit 20 includes a first auxiliary control transistor element 26, and a first control transistor element 24, wherein the first signal input node 12 is coupled to a control terminal of the first control transistor element 24 and a control terminal of the first auxiliary control transistor element 26. A path connected in parallel to the first control transistor element 24 includes the first auxiliary control transistor element 26.

The term “a path connected in parallel to the first control transistor element” has no geometrical layout limitation but determines existence of connections of an amplifier assembly elements/units.

As shown in FIG. 1, the first input circuit 20 may include a first clamping circuit 28, wherein the path connected in parallel to the first control transistor element 26 may include, connected in series, the first clamping circuit 28.

As also shown in FIG. 1, the second input circuit 30 may include a second auxiliary control transistor element 36, and a second control transistor element 34, wherein the second signal input node 14 may be coupled to a control terminal of the second control transistor element 34 and a control terminal of the second auxiliary control transistor element 36. A path connected in parallel to the second control transistor element 34 may include the second auxiliary control transistor element 36.

As can be seen in FIG. 1, the second input circuit 30 may include a second clamping circuit 38, wherein the path connected in parallel to the second control transistor element 34 may include, connected in series, the second clamping circuit 38.

When the input voltage at the first signal input node 12 increases, the first clamping circuit 28 may clamp the path connected in parallel to the first control transistor element 24. In particular, the first auxiliary control transistor element may be clamped from control of the output of the first input circuit 20. As a result, the first auxiliary control transistor element 26 may become decoupled and the first control transistor element 24 may take over.

When the input voltage at the second signal input node 14 increases, the second clamping circuit 38 may clamp the path connected in parallel to the second control transistor element 34. In particular, the second auxiliary control transistor element may be clamped from control of the output of the second input circuit 30. As a result, the second auxiliary control transistor element 36 may become decoupled and the first control transistor element 34 may take over.

On the other hand, when the first and/or the second auxiliary control transistor elements 26, 36 may be in the linear region, the output voltage of the first and/or second input circuits 20, 30 may reach to a source node of the first and/or second auxiliary control transistor element, respectively. So, the first and/or second control transistor element 24, 34 may not be operated when a first and/or second input signal is about a supply voltage Vdd, respectively.

In some embodiments, the amplifier assembly may comprise a biasing current source 18 for biasing the first control transistor element 24 and/or the second control transistor element 34. The biasing current source 18 may therefore be connected in series with the first control transistor element 24 and/or the second control transistor element 34.

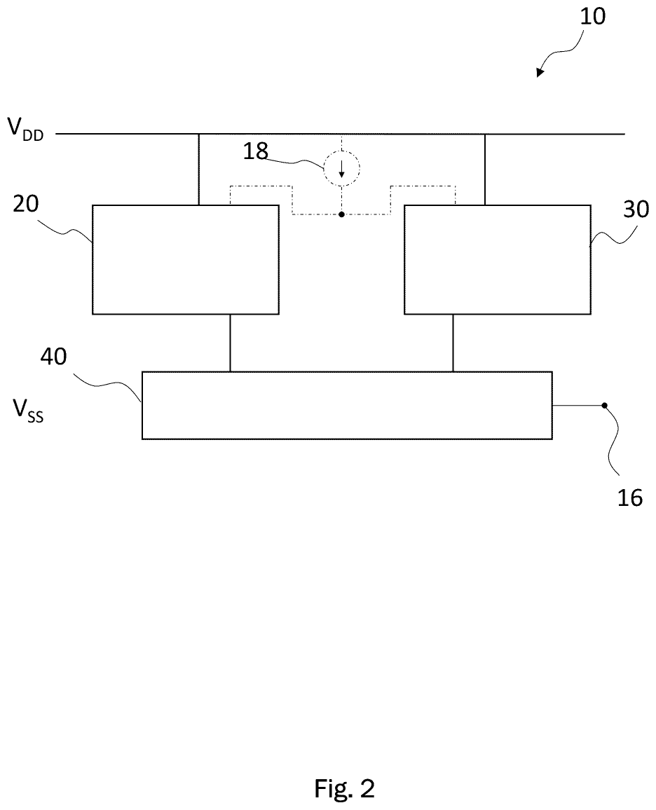

FIG. 2 schematically shows an example of an amplifier assembly 10 according to another embodiment. FIG. 2 is based on FIG. 1. FIG. 1 shows a configuration of the amplifier assembly 10 where the load circuit 40 is coupled to the supply voltage V_{DD} and the first and second input circuits 20, 30 form paths from the load circuit 40 to a second potential V_{SS}, which may be ground. FIG. 2 shows an alternative configuration where the first and second input circuits 20, 30 are connected to the supply voltage V_{DD} and the load circuit 40 forms a path from the first and second input circuits 20, 30 to a second potential V_{SS}, which may be ground. In this connection, the circuit configurations of the first input circuit 20, the second input circuit 40 and the load circuit 40 may be adapted accordingly to such a reconfiguration.

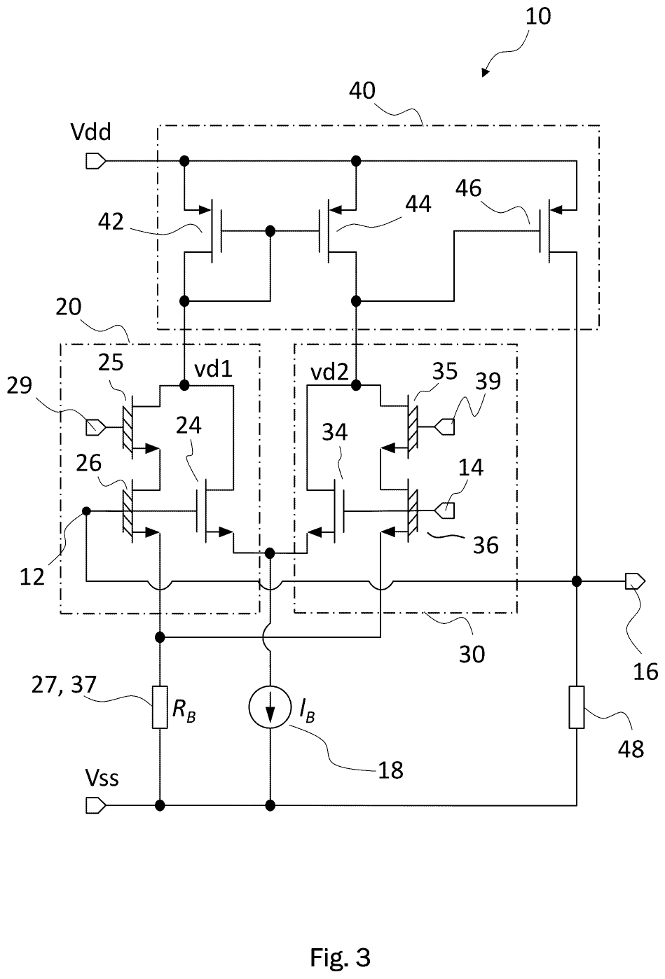

FIG. 3 schematically shows an example of an amplifier assembly 10 according to another embodiment. FIG. 3 is based on the embodiment shown in FIG. 1. Further, the amplifier assembly shown in FIG. 3 may be adapted similarly to the embodiment shown in FIG. 1 to be in-line with the embodiment shown in FIG. 2. Identical or analogous circuit elements are therefore not described again.

As can be seen in FIG. 3, the first clamping circuit 28 may include a first clamping transistor element 25, wherein a control terminal of the first clamping transistor element 25 may be controlled by an electrical quantity at a biasing input node 29.

When the input voltage at the first signal input node 12 increases and reaches an input voltage at the biasing input node 29, the first clamping transistor element 25 may clamp or may start to clamp the first auxiliary control transistor element 26. As a result, the first auxiliary control transistor element 26 may be decoupled and, thus, turned off, and the first control transistor element 24 takes over. That means the output vd1 of the first input circuit 20 provided to the load circuit 40 is controlled basically by the first auxiliary control transistor element 26 for low input voltages at the first input node 12 and is controlled basically by the first control transistor element 24 for high input voltages at the first input node 12.

Further, as shown in FIG. 3, the second clamping circuit 38 may include a second clamping transistor element 35, wherein a control terminal of the second clamping transistor element 35 may be controlled by an electrical quantity at a biasing input node 39.

When the input voltage at the second signal input node 14 increases and reaches an input voltage at the biasing input node 39, the second clamping transistor element 35 may clamp or may start to clamp the second auxiliary control transistor element 36. As a result, the second auxiliary control transistor element 36 may be decoupled and, thus, turned off and the second control transistor element 34 takes over. That means the output vd2 of the second input circuit 30 provided to the load circuit 40 is controlled basically by the second auxiliary control transistor element 36 for low input voltages at the second input node 14 and is controlled basically by the second control transistor element 34 for high input voltages at the second input node 14.

In some embodiments, the biasing input node 29 may be coupled to the biasing input node 39. In some other embodiments, the biasing input node 29 may be decoupled from the biasing input node 39.

The first clamping circuit may comprise a biasing resistor 27 being connected in series with the first clamping transistor element 25 and/or the second clamping circuit may comprise a biasing resistor 37 being connected in series with the second clamping transistor element 35. As can be seen in FIG. 3, the first and second biasing resistor 27, 37 may be shared with each other by the first clamping circuit and the second clamping circuit 28, 38.

The first clamping transistor element 25, the first auxiliary control transistor element 26, the first control transistor element 24, the second clamping transistor element 35, the second auxiliary control transistor element 36, and/or the second control transistor element 34 may be in some embodiments n-MOS transistor elements. In some configurations, all transistor elements of the first input circuit 20 and/or of the second input circuit 30 may be n-MOS transistor elements.

In some embodiments, the first clamping transistor element 25, the first auxiliary control transistor element 26, the second clamping transistor element 35, and/or the second auxiliary control transistor element 36 may be native MOS transistor elements. In some configurations, the first control transistor element 24 and/or the second control transistor element 34 may be standard MOS transistor elements.

As shown in FIG. 3, the load circuit 40 may include an output transistor element 46 for controlling an output 16 of the amplifier assembly 10 based on an output electrical quantity vd1 of the first input circuit 20 and based on an output electrical quantity vd2 of the second input circuit 30. In some configurations, the first input circuit 20 and the second input circuit 30 affect an electrical quantity at a control terminal of the output transistor element 46.

In some alternative embodiments, the load circuit may control an output 16 of the amplifier assembly 10 based on an output electrical quantity vd1 of the first input circuit 20 and based on an output electrical quantity vd2 of the second input circuit 30 without an output transistor element 46 by directly outputting a control signal, which would be provided to the output transistor element 46.

As shown in FIG. 3, the load circuit may include a current mirror circuit 42, 44 and an output transistor element 46, wherein the current mirror circuit 42, 44 may be coupled to the first input circuit 20, the second input circuit 30. In some embodiments, an output of the current mirror circuit may be directly output at the output node 16. In some alternative configurations, the current mirror circuit may be coupled to the first input circuit 20, the second input circuit 30 and the output transistor element 46, and the output transistor element 46 controls an output 16 of the amplifier assembly 10.

As can be seen in FIG. 3, the load circuit may include an output transistor element 46, a first load transistor element 42 and a second load transistor element 44, wherein the first input circuit 20 may be coupled to the control terminal of the first load transistor element 42, to the control terminal of the second load transistor element 44, and to the channel of the first load transistor element 42, the second input circuit 30 may be coupled to the channel of the second load transistor element 44 and to the control terminal of the output transistor element 46, and the channel of the output transistor element 46 is coupled to the output 16 of the amplifier assembly 10. In some embodiments, the output transistor element 46 may be omitted and a signal, which would be provided to the control terminal of the output transistor 46 element, may be directly provided to the output 16 of the amplifier assembly.

In some configurations, the output transistor element 46, the first load transistor element 42 and/or the second load transistor element 44 may be p-MOS transistor elements. In some embodiments, all transistor elements of the load circuit 40 may be p-MOS transistor elements.

In some configurations, the output transistor element 46, the first load transistor element 42 and/or the second load transistor element 44 may be standard MOS transistor elements. In some embodiments, all transistor elements of the load circuit 40 may be standard MOS transistor elements.

In some configurations, the output 16 of the amplifier assembly 10 may be coupled to the first signal input node 12 or to the second signal input node 14. Such a configuration may be used to obtain a voltage follower, in particular a wide-range voltage follower.

In some embodiments, the amplifier assembly may comprise a load resistance R_{L} 48, which is coupled to the output node 16.

In addition to rail-to-rail operation, the disclosed amplifier assembly may optimize input offset voltage. At the low-voltage input range, native n-MOS transistor elements 25, 26, 35, 36 operate, whose threshold voltage is small because native n-MOS does not have a threshold voltage adjustment process. Thus, native n-MOS transistor elements 25, 26, 35, 36 brings to improve voltage accuracy.

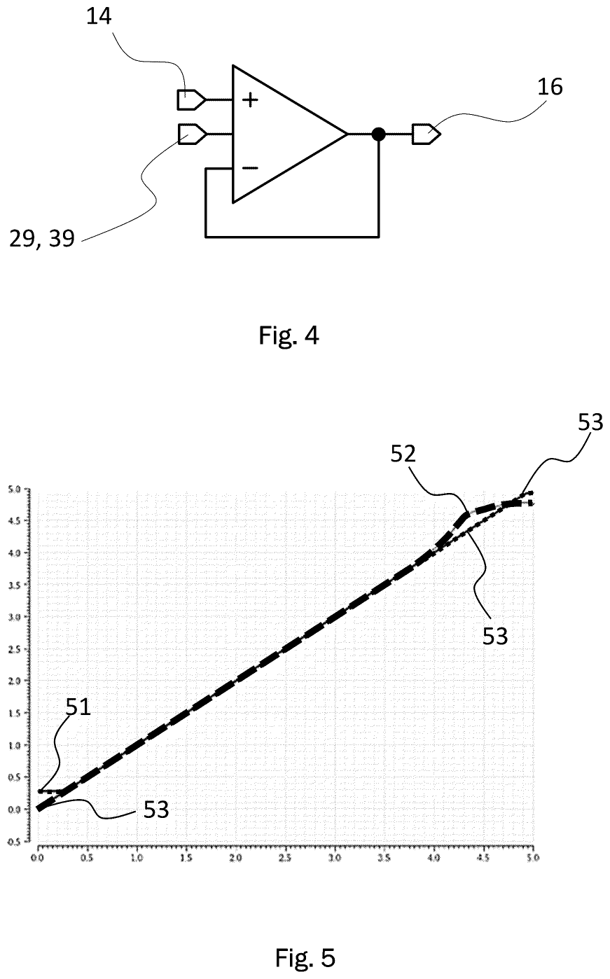

FIG. 4 schematically shows an example of an amplifier assembly according to an embodiment, being used as a voltage follower. As can be seen in FIG. 4, the biasing input node 29 and the biasing input node 39 are summed up as a single biasing input node. Further, the output of the amplifier assembly is coupled to the first signal input node 12, which forms a negative input of the amplifier assembly.

FIG. 5 schematically shows examples of transfer functions of an amplifier assembly according to embodiments, being connected as shown in FIG. 4. On the x-axis the input signal is provided in volt and on the y-axis the output signal is provided in units of Volts.

Graph 51 in FIG. 5 shows the transfer function of an amplifier assembly as shown in FIG. 3 without the paths connected in parallel to the first and second control transistor elements 24, 34. Graph 52 shows in FIG. 5 the transfer function of an amplifier assembly as shown in FIG. 3 without the clamping transistor elements 25, 35 (the clamping transistor elements 25 and 35 are replaced by a respective transmission line). Graph 53 shows in FIG. 5 the transfer function of an amplifier assembly exactly as described above by means of FIG. 3.

Having a look at the graphs 51 and 52, it is apparent that the first and second auxiliary control transistor elements 26, 36 increase accuracy of the amplifier assembly for low input voltages. However, such an adaption causes an overshot in the transfer function for high input voltages. By implementing the first and second clamping transistor elements 25 and 35, such an overshot for high input voltages can be avoided with low effort, since the first and second clamping transistor elements 25, 35 decouple the first and second auxiliary control transistor elements 26, 36 by clamping the paths connected in parallel to the first and second control transistor elements 24, 34, respectively. Thus, the first and/or second auxiliary control transistor element 26, 36 may be turned off, respectively.

The transfer functions shown in FIG. 5 are based on simulations with the following amplifier assembly configurations:

| | Parameter |
|---|---|
| First and second load transistor element 42, | Multiplier*(W/L) = 4*(2/11) |
| 44 | |
| Output transistor element 46 | Multiplier*(W/L) = 2*(4/6) |
| First and second control transistor element | Multiplier*(W/L) = 4*(10/1) |
| 24, 34 | |
| First and second auxiliary control transistor | Multiplier*(W/L) = 1*(2/5) |
| element 26, 36 and first and second clamping | |
| transistor element 25, 35 | |
| Biasing resistor R_{B} 27, 37 | Resistance = 2 MΩ |
| Load resistance R_{L} 48 | Resistance = 2 MΩ |
| Bias current I_{B} | Bias current = 1 μA |
| Bias voltage at biasing node | Bias voltage = 1.2 V |

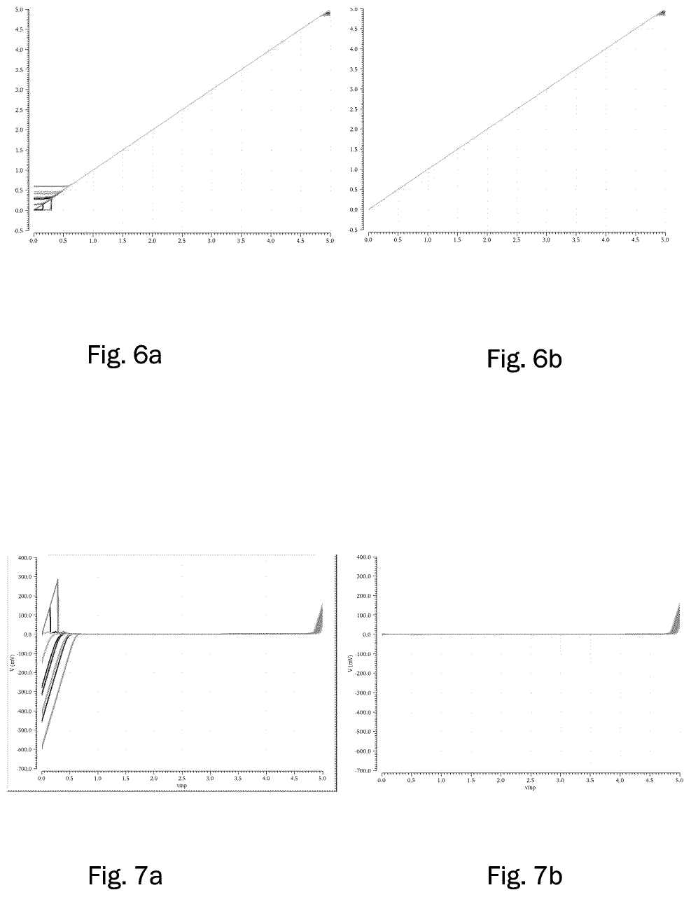

FIG. 6a schematically shows an example of dependencies of the transfer functions on temperature of an amplifier assembly without an auxiliary control transistor element and without a clamping transistor element.

FIG. 6b schematically shows an example of dependencies of the transfer functions on temperature of an amplifier assembly according to an embodiment, wherein the first auxiliary control transistor element 26, the second auxiliary control transistor element 36, the first clamping transistor element 25 and the second transistor clamping element 35 are native transistor elements.

In both FIG. 6a and FIG. 6b, the amplifier assembly is connected as shown in FIG. 4. On the x-axes, the input voltage provided at the signal input node 14 is shown and, on the y-axes, the output voltage provided at the output node 16 is scaled up.

Within the diagrams, graphs of several processes and temperatures (−40° C., 25° C. and 150° C.) are shown. As can be seen from FIG. 6a and FIG. 6b, accuracy is much higher for low input voltages, when the first auxiliary control transistor element 26, the second auxiliary control transistor element 36, the first clamping transistor element 25 and the second transistor clamping element 35 are provided. Based on these results, when the first auxiliary control transistor element 26, the second auxiliary control transistor element 36, the first clamping transistor element 25 and the second transistor clamping element 35 are provided, the input voltage range can be increased and therefore the overall rail-to-rail range can be improved.

FIG. 7a and FIG. 7b schematically show an example of an error between the transfer functions shown in FIG. 6a and FIG. 6b and an ideal, linear rail-to-rail transfer function, respectively. On the x-axes, the voltage provided to the second signal input node 14 is shown. On the y-axes, the error between the output voltage as shown in FIGS. 6a and 6b and the ideal, linear rail-to-rail transfer function, respectively, is provided. The error is scaled in mV.

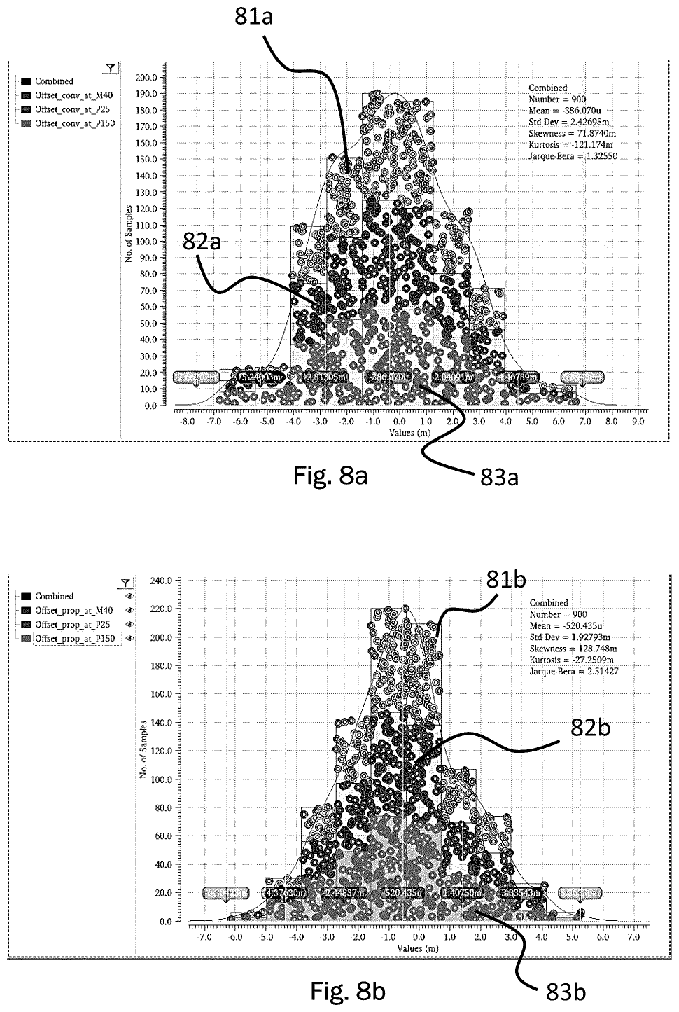

FIG. 8a shows an example of a result of a Monte Carlo simulation across temperature of an amplifier assembly according to an embodiment as shown in FIG. 3, wherein the auxiliary control transistor elements are standard MOS transistor elements. FIG. 8b shows an example of the result of a Monte Carlo simulation across temperature of an amplifier assembly according to an embodiment as shown in FIG. 3, wherein the auxiliary control transistor elements are native MOS transistor elements. FIG. 8a and FIG. 8b show results for Monte Carlo simulations with each 300 runs across temperature values of −40° C., 25° C., 150° C. with a predefined voltage of 1V at the second signal input node 14.

A performance summary of the Monte Carlo simulations is provided as follows:

| Process | | VIS 250-nm CMOS BCD | |
|---|---|---|---|
| Architecture - First and second | | standard | native |
| auxiliary control transistor element | | transistor | transistor |
| 26, 36 and first and second clamping | | elements | elements |
| transistor element 25, 35 are: | | | |
| Output voltage error | Typical @ Room | 0.33 V < Vout < | 0 V < Vout < |
| at output node 16 | Temperature | 4.93 V | 4.93 V |
| within +/− 10 mV | Process & Temp. | 0.63 V < Vout < | 0 V < Vout < |
| (Vdd = 5 V) | | 4.83 V | 4.83 V |

| | | |
|---|---|---|
| Variation of input offset voltage | σ = 2.43 mV | σ = 1.93 mV |
| (Voltage at second input node = 1 V, | | |
| Vdd = 5 V, Temp. −40° C., 25° C., | | |
| 150° C. = | | |
| Quiescent current Iq | Iq_typ = 5.0 μA | Iq_typ = 6.0 μA |
| (Voltage at second input node = 1 V, | (3.5 μA < | (5.2 μA < |
| Vdd = 5 V, Process & Temp.) | Iq < 7.0 μA) | Iq < 8.4 μA) |

Simulation points 81a refer to a simulation temperature of −40° C. Simulation points 81b refer to a simulation temperature of +25° C. and simulation points 81c to a simulation temperature of +150° C.

Therefore, even if the transistor elements 25, 26, 35, 36 being native transistor elements employ different aspect ratio comparing with the transistor elements 25, 26, 35, 36 being standard transistor elements, the variation of the amplifier assembly with the native configuration is 0.5 mV (at 1σ) smaller than the amplifier assembly with the standard configuration. Thus, reducing the variation of the output voltage at 1σ by 0.5 mV helps to improve overall accuracy. Therefore, by using native transistor elements for the transistor elements 25, 26, 35,36 enables to improve the input offset voltage as well as rail-to-rail operation. These improvements may be relevant for automotive products in particular.

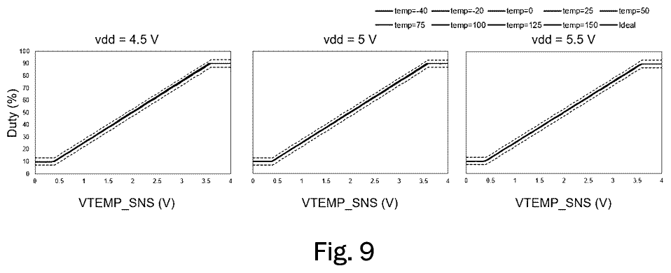

FIG. 9 schematically shows an example of measurement results of a PWM (Pulse Width Modulation) converter across supply voltage and temperature, wherein an amplifier assembly as shown by one of FIGS. 1 to 3 is used. On the horizontal axes input voltages are applied and on the vertical axes the generated duty ratio is shown. The dotted lines show an +/−3% error from an ideal result. The supply voltage measurement points are Vdd=4.5V, Vdd=5V and Vdd=5.5V. For each of those supply voltages, measurements are executed at temperatures of −40° C., −20° C., 0° C., 25° C., 50° C., 75° C., 100° C., 125° C. and 150° C.

As can be seen from FIG. 9, the measurement graphs are very close to the ideal curve and are all within the +/−3% error range. Therefore, the disclosed amplifier assembly increases a PWM input range and accuracy, wherein the circuit configuration is simplified. Thus, the disclosed amplifier assembly contribute cost reduction as well as circuit performance.

Within this overall disclosure, voltages of transistor elements may refer to the commonly known voltages characterizing a transistor element, like a gate-source voltage, a drain source voltage, etc.

Voltages of nodes shown in the present disclosure without any reference potential may refer to a common reference potential, e.g. ground.

It is also noted that embodiments shown by means of the figures and description as discussed above may be combined with each other.

In some embodiments, circuit elements may be added, split up, summed up, omitted without affecting the teachings of the present disclosure.

1. Amplifier assembly suitable for use as a rail-to-rail amplifier including:
a first input circuit connected to a first signal input node for a first input level range;
a second input circuit connected to a second signal input node for a second input level range;
a load circuit coupled to the first input circuit, the second input circuit and an output node of the amplifier assembly,
wherein
the first input circuit includes a first auxiliary control transistor element, and a first control transistor element, wherein
the first signal input node is coupled to a control terminal of the first control transistor element and a control terminal of the first auxiliary control transistor element;
a path connected in parallel to the first control transistor element includes the first auxiliary control transistor element.

2. The amplifier assembly according to claim 1, wherein
the first input circuit includes a first clamping circuit, wherein
the path connected in parallel to the first control transistor element includes, connected in series, the first clamping circuit.

3. The amplifier assembly according to claim 2, wherein
the first clamping circuit includes a first clamping transistor element, wherein a control terminal of the first clamping transistor element is controlled by an electrical quantity at a biasing input node.

4. The amplifier assembly according to claim 1, wherein
the second input circuit includes a second auxiliary control transistor element, and a second control transistor element, wherein
the second signal input node is coupled to a control terminal of the second control transistor element and a control terminal of the second auxiliary control transistor element;
a path connected in parallel to the second control transistor element includes the second auxiliary control transistor element.

5. The amplifier assembly according to claim 4, wherein
the second input circuit includes a second clamping circuit, wherein
the path connected in parallel to the second control transistor element includes, connected in series, the second clamping circuit.

6. The amplifier assembly according to claim 5, wherein
the second clamping circuit includes a second clamping transistor element, wherein a control terminal of the second clamping transistor element is controlled by an electrical quantity at a biasing input node.

7. The amplifier assembly according to claim 1, wherein
the first clamping transistor element, the first auxiliary control transistor element, the first control transistor element, the second clamping transistor element, the second auxiliary control transistor element, and/or the second control transistor element are n-MOS transistor elements, and/or
all transistor elements of the first input circuit and/or of the second input circuit are n-MOS transistor elements.

8. The amplifier assembly according to claim 1, wherein
the first clamping transistor element, the first auxiliary control transistor element, the second clamping transistor element, and/or the second auxiliary control transistor element are native MOS transistor elements; and/or
the first control transistor element and/or the second control transistor element are standard MOS transistor elements.

9. The amplifier assembly according to claim 1, wherein
the load circuit includes an output transistor element for controlling an output of the amplifier assembly based on an output electrical quantity of the first input circuit and based on an output electrical quantity of the second input circuit.

10. The amplifier assembly according to claim 1, wherein
the load circuit includes an output transistor element, wherein the first input circuit and the second input circuit affect an electrical quantity at a control terminal of the output transistor element.

11. The amplifier assembly according to claim 1, wherein
the load circuit includes a current mirror circuit and an output transistor element, wherein
the current mirror circuit is coupled to the first input circuit, the second input circuit and the output transistor element, and
the output transistor element controls an output of the amplifier assembly.

12. The amplifier assembly according to claim 1, wherein
the load circuit includes an output transistor element, a first load transistor element and a second load transistor element, wherein
the first input circuit is coupled to the control terminal of the first load transistor element, to the control terminal of the second load transistor element, and to the channel of the first load transistor element,
the second input circuit is coupled to the channel of the second load transistor element and to the control terminal of the output transistor element, and
the channel of the output transistor element is coupled to the output of the amplifier assembly.

13. The amplifier assembly according to claim 12, wherein
the output transistor element, the first load transistor element and/or the second load transistor element are p-MOS transistor elements, and/or
all transistor elements of the load circuit are p-MOS transistor elements.

14. The amplifier assembly according to claim 12, wherein
the output transistor element, the first load transistor element and/or the second load transistor element are standard MOS transistor elements, and/or
all transistor elements of the load circuit are standard MOS transistor elements.

15. The amplifier assembly according to claim 1, wherein
the output of the amplifier assembly is coupled to the first signal input node or to the second signal input node.
